(19) United States
(12) Patent Application Publication
(10) Pub. No.: US 2009/0068767 A1
(43) Pub. Date: Mar. 12, 2009

(54) TUNING VIA FACET WITH MINIMAL RIE LAG

(75) Inventors: Stephen Sirard, San Jose, CA (US); Mikio Nagai, Fremont, CA (US); Kenji Takeshita, Sunnyvale, CA (US); Sridharan Srivatsan, Fremont, CA (US); Jungmin Ko, Mountain View, CA (US)

Correspondence Address: Beyer Law Group LLP, P.O. BOX 1687, Cupertino, CA, 95015-1687, US

(73) Assignee: LAM RESEARCH CORPORATION, Fremont, CA (US)

(21) Appl. No.: 11/854,038

(22) Filed: Sep. 12, 2007

(51) Int. Cl. H01L 21/00

(52) U.S. Cl. 438/8; 257/E21.249

(57) ABSTRACT

A method for designing an etch recipe is provided. An etch is performed, comprising providing an etch gas with a set halogen to carbon ratio, forming a plasma from the etch gas, and etching trenches over via. Via faceting is measured. The halogen to carbon ratio is reset according to the measured via faceting, where the halogen to carbon ratio is increased if too much faceting is measured and the halogen to carbon ratio is decreased if too little faceting is measured. The previous steps are repeated until a desired amount of faceting is obtained.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer.

### SUMMARY OF THE INVENTION

To achieve the foregoing and in accordance with the purpose of the present invention a method for designing an etch recipe is provided. An etch is performed, comprising providing an etch gas with a set halogen to carbon ratio, forming a plasma from the etch gas, and etching trenches over vias. ESC bias voltage is set such to provide optimal trench profiles for device performance. Via faceting is measured. The halogen to carbon ratio is reset according to the measured via faceting, where the halogen to carbon ratio is increased if too much faceting is measured and the halogen to carbon ratio is decreased if too little faceting is measured. The previous steps are repeated until a desired amount of faceting is obtained.

In another manifestation of the invention a method of manufacturing semiconductor devices is provided. An etch is performed comprising providing an etch gas with a set halogen to carbon ratio, forming a plasma from the etch gas, and etching trenches over vias. Via faceting is measured. The halogen to carbon ratio is reset according to the measured via faceting, where the halogen to carbon ratio is increased if too much faceting is measured and the halogen to carbon ratio is decreased if too little faceting is measured. The previous steps are repeated until a desired amount of faceting is obtained. A plurality of trenches over vias is etched in a plurality of wafers using the halogen to carbon ratio used for obtaining the desired amount of faceting.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIGS. 2A-C are schematic cross-sectional views of a stack processed according to an embodiment of the invention.

FIG. 3 is a schematic view of a plasma processing chamber that may be used in practicing the invention.

FIGS. 4A-B illustrate a computer system, which is suitable for implementing a controller used in embodiments of the present invention.

FIG. 5 is a graph of normalized Y-facet versus ESC bias for different etch chemistries of CF₄/NF₃, CF₄, and CF₄/CHF₃.

FIG. 6 is a graph of RIE lag versus ESC bias for the different etch chemistries.

FIG. 7 is a graph of normalized Y-facet versus chemistry at −280 volt bias for NF₃ and CHF₃.

FIG. 8 is a graph of normalized Y-facet versus RIE lag for CF₄, NF₃, and CHF₃.

FIG. 9 illustrates how the x-facet and y-facet are measured.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

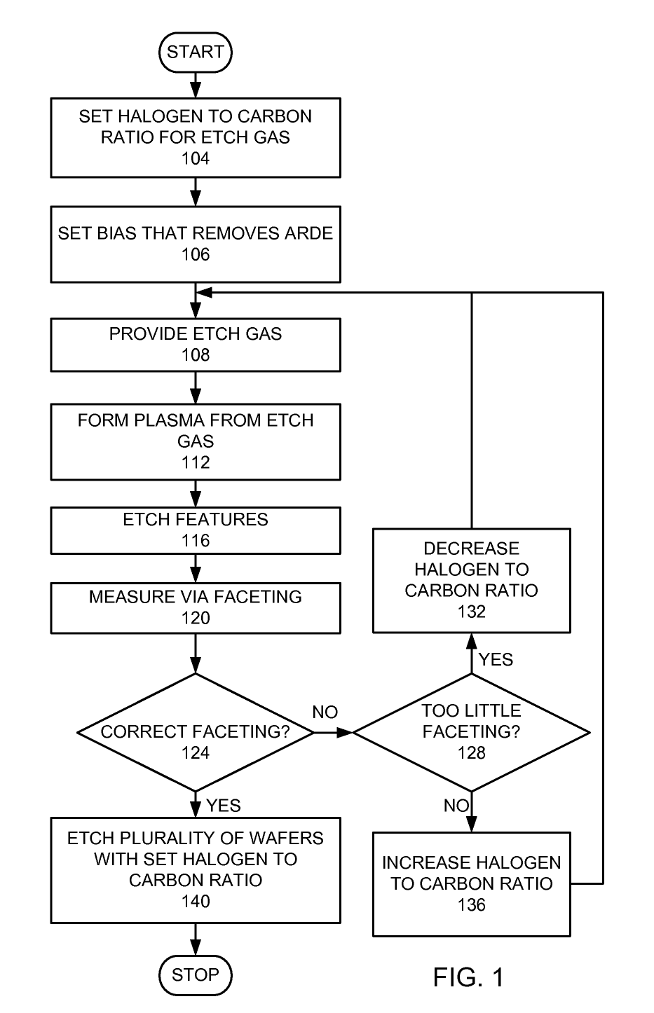

To facilitate understanding, FIG. 1 is a high level flow chart of a process that may be used in an embodiment of the invention. A halogen to carbon ratio for an etch gas is set (step 104). An electrostatic chuck (ESC) bias is set to remove ARDE (step 106). This may be done using a loop, that sets an initial ESC bias, performs an etch, measures the ARDE, and repeats the process until the ARDE is sufficiently reduced. An etch gas is provided with the set halogen to carbon ratio (step 108). A plasma is formed from the etch gas (step 112). Trenches patterned over previously etched via structures (Dual Damascene) are etched (step 116). Via faceting is measured (step 120). A determination is made on whether a correct amount of via faceting is obtained (step 124). If the correct amount of via faceting is obtained a plurality of wafers may be etched using an etch gas with the set halogen to carbon ratio. If the correct amount of via faceting is not obtained then a determination is made on whether there was too little faceting (step 128). If there was too little faceting the halogen to carbon ratio is decreased (step 132). If there was too much faceting the halogen to carbon ratio is increased (step 136). Then the process returns to providing the etch gas (step 108). This cycle is repeated until the correct amount of faceting is obtained (step 124). Then the resulting recipe with the resulting halogen to carbon ratio is used to etch a plurality of wafers (step 140).

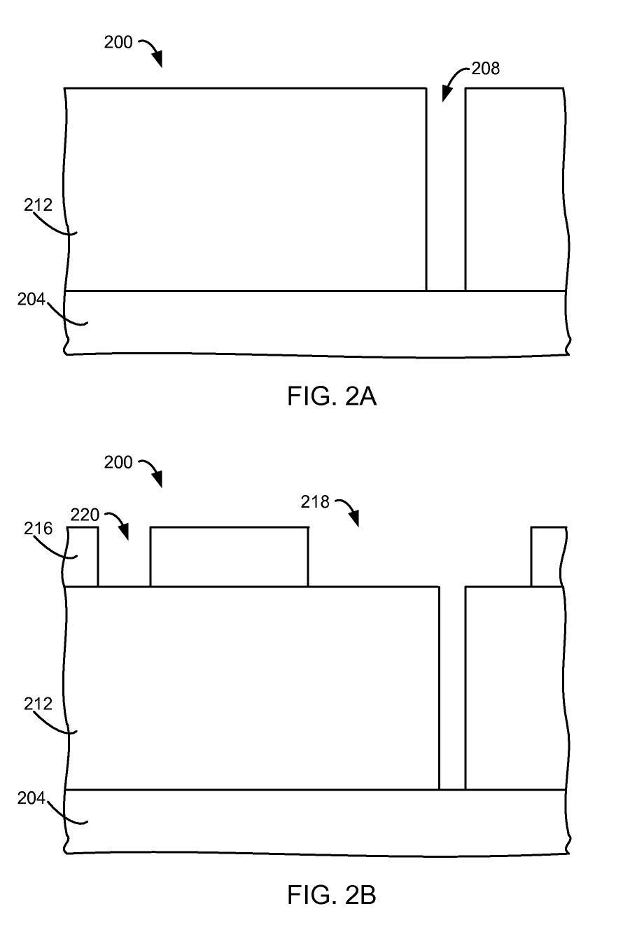

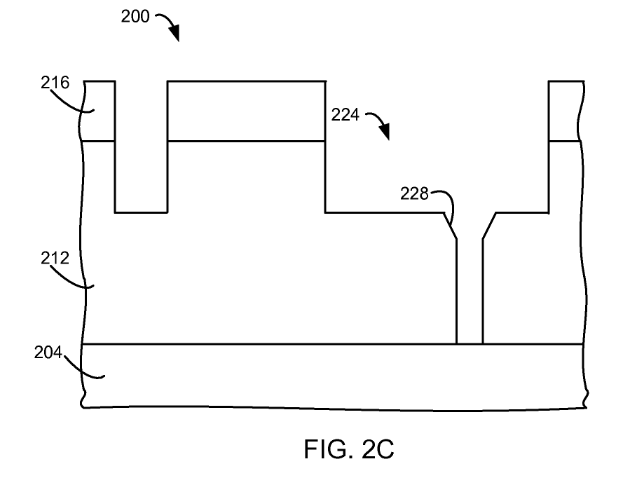

In a dual damascene via first process, vias are formed in a dielectric layer. FIG. 2A is a cross-sectional view of a stack 200 with substrate 204 over which a via 208 has been formed in a dielectric layer 212. A patterned photoresist mask 216 is formed over the dielectric layer 212, as shown in FIG. 2B. The patterned mask is patterned to provide mask features. In this example, wide mask features with wider widths (higher CD's) 218 and narrow mask features 220 with narrower widths (lower CD's) are provided. The narrow mask features 220 provide higher aspect ratio features than the wide mask features 218. In general the narrower mask features 220 have lower widths than the wider mask features 218. Preferably, the widths of the wider mask features 218 to the widths of the narrower mask features 220 have a ratio greater than 1:2. Generally, the wider mask features 218 are found in isolated areas of a chip and narrower mask features 220 are found in a more densely patterned area of a chip.

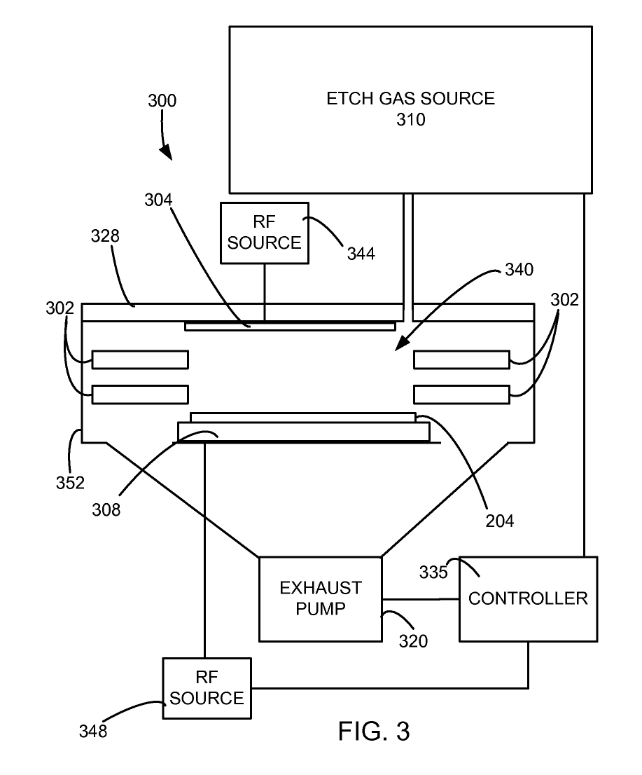

The stack 200 is placed in a processing chamber. FIG. 3 is a schematic view of a processing chamber 300 that may be used in this example of the invention for etching and stripping the photoresist mask. The plasma processing chamber 300 comprises confinement rings 302, an upper electrode 304, a lower electrode 308, a gas source 310 connected through a gas inlet, and an exhaust pump 320 connected to a gas outlet. Within plasma processing chamber 300, the substrate 204 is positioned upon the lower electrode 308. The lower electrode 308 incorporates a suitable substrate chucking mechanism (e.g., electrostatic, mechanical clamping, or the like) for holding the substrate 204. The reactor top 328 incorporates the upper electrode 304 disposed immediately opposite the lower electrode 308. The upper electrode 304, lower electrode 308, and confinement rings 302 define the confined plasma volume. Gas is supplied to the confined plasma volume by the gas source 310 and is exhausted from the confined plasma volume through the confinement rings 302 and an exhaust port by the exhaust pump 320. A first RF source 344 is electrically connected to the upper electrode 304. A second RF source 348 is electrically connected to the lower electrode 308. Chamber walls 352 surround the confinement rings 302, the upper electrode 304, and the lower electrode 308. Both the first RF source 344 and the second RF source 348 may comprise a 27 MHz power source and a 2 MHz power source. Different combinations of connecting RF power to the electrode are possible. In the case of Lam Research Corporation's Dual Frequency Capacitive (DFC) System, made by LAM Research Corporation™ of Fremont, Calif., which may be used in a preferred embodiment of the invention, both the 27 MHz and 2 MHz power sources make up the second RF power source 348 connected to the lower electrode, and the upper electrode is grounded. A controller 335 is controllably connected to the RF sources 344, 348, exhaust pump 320, and the gas source 310. The DFC System would be used when the layer to be etched 208 is a dielectric layer, such as silicon oxide or organo silicate glass.

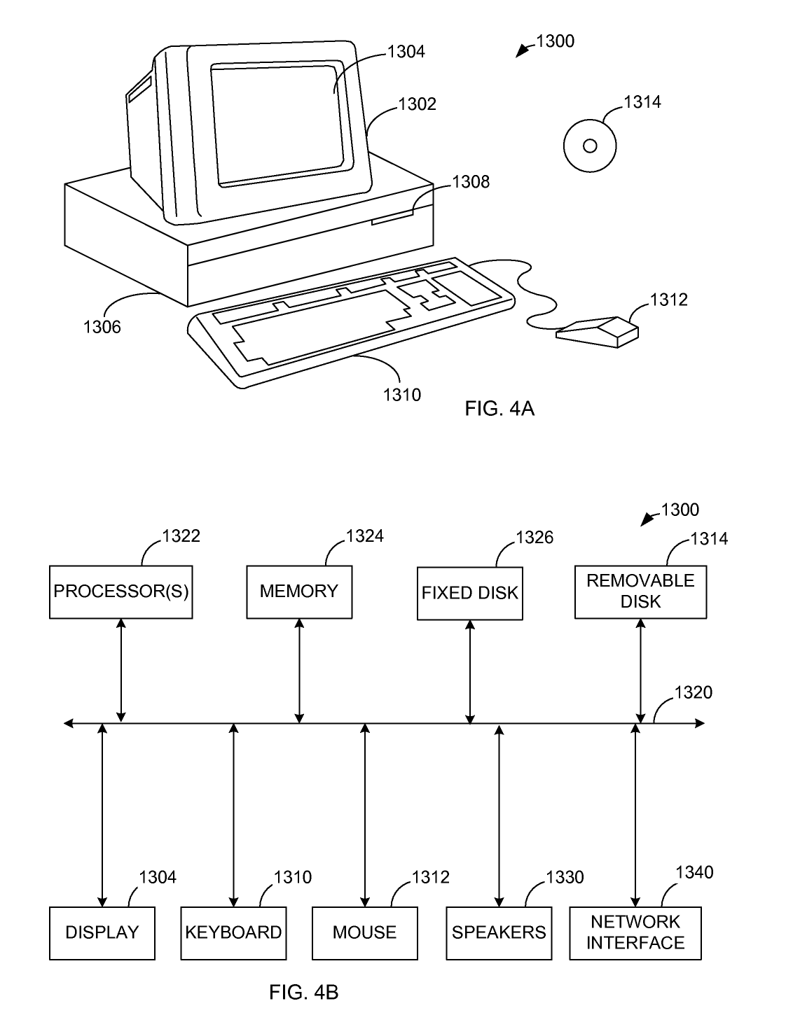

FIGS. 4A and 4B illustrate a computer system 1300, which is suitable for implementing a controller 335 used in embodiments of the present invention. FIG. 4A shows one possible physical form of the computer system. Of course, the computer system may have many physical forms ranging from an integrated circuit, a printed circuit board, and a small handheld device up to a huge super computer. Computer system 1300 includes a monitor 1302, a display 1304, a housing 1306, a disk drive 1308, a keyboard 1310, and a mouse 1312. Disk 1314 is a computer-readable medium used to transfer data to and from computer system 1300.

FIG. 4B is an example of a block diagram for computer system 1300. Attached to system bus 1320 is a wide variety of subsystems. Processor(s) 1322 (also referred to as central processing units, or CPUs) are coupled to storage devices, including memory 1324. Memory 1324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 1326 is also coupled bi-directionally to CPU 1322; it provides additional data storage capacity and may also include any of the computer-readable media described below. Fixed disk 1326 may be used to store programs, data, and the like and is typically a secondary storage medium (such as a hard disk) that is slower than primary storage. It will be appreciated that the information retained within fixed disk 1326 may, in appropriate cases, be incorporated in standard fashion as virtual memory in memory 1324. Removable disk 1314 may take the form of any of the computer-readable media described below.

CPU 1322 is also coupled to a variety of input/output devices, such as display 1304, keyboard 1310, mouse 1312, and speakers 1330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 1322 optionally may be coupled to another computer or telecommunications network using network interface 1340. With such a network interface, it is contemplated that the CPU might receive information from the network, or might output information to the network in the course of performing the above-described method steps. Furthermore, method embodiments of the present invention may execute solely upon CPU 1322 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

A halogen to carbon ratio is selected for an etch gas (step 104). In this example, the halogen is fluorine. The etch gas is provided from the gas source to the confined plasma volume (step 108). The electrodes are energized to form a plasma from the etch gas (step 112).

In an example of an etch recipe, an etch gas is flowed from the gas source 310 into the plasma processing tool. In this example, the etch gas is 300 sccm of CF₄. The chamber pressure is maintained at 100 mTorr. The etch gas is transformed to an etching plasma. In this example, 500 watts at 27 MHz of power is provided through the electrodes. In this example the halogen to carbon ratio is measured by flow rate and is 4:1 If halogen to carbon ratio needs to be decreased, a second gas such as C₄F₈ or H₂ may be added to decrease the halogen to carbon ratio. Conversely, if halogen to carbon ratio needs to be increased a second gas such as O₂ or NF₃ may be added.

The via faceting is measured (step 120). FIG. 2C is a cross-sectional view of the stack 200 after it is etched with resulting via faceting 228. Since this example uses a via first dual damascene process, the wider mask features are used to form trenches 224. Different schemes may be used to reduce via faceting such as partially filling in the vias, however some faceting normally occurs. Via faceting is defined here as faceting at the transition from a via to a trench in a via first dual damascene process.

Some degree of faceting may be desirable to enable barrier and metal filling of the features. Too much faceting is undesirable and degrades electrical properties of the device. In some examples, too little faceting is undesirable. A determination is made on whether the measured faceting is about equal to the desired faceting (step 124). If the measured faceting is not about equal to the desired faceting a determination is made of whether to increase or decrease faceting. In this example, this is done by determining if there is too little faceting (step 128). If there is too little faceting, the halogen to carbon ratio is decreased (step 132). If there is not enough faceting then the halogen to carbon ratio is increased (step 136). The process goes back to step 108, where the new etch gas with the new etch gas ratio is used. This process is repeated until the desired faceting is reached (step 124). The etch recipe has now been determined. The etch recipe may now be used to etch a plurality of wafers using the etch gas found when the desired faceting is reached.

It has been found that the wider features tend to etch faster than the narrower features, which is called aspect ratio dependent etching (ARDE) or reactive ion etch (RIE) lag. To minimize ARDE or RIE lag, a bias voltage is applied at a sufficient amplitude to minimize ARDE or RIE lag. It has been found that an increase in the bias voltage increases faceting. Without wishing to be bound by theory, it is believed that electrons form an electron charge on the surface of the mask material. For high aspect ratio features, the features are thin enough to allow the electron charge to slow etching ions that are positively charged, reducing the etch rate of the high aspect ratio features. Wider low aspect ratio features have less of a slowing effect, so that the etch rate is not as significantly reduced, resulting in a higher etch rate for the lower aspect ratio devices. The difference in etching speeds causes RIE-lag (reactive ion etch-lag) or ARDE (Aspect Ratio Dependent Etch). It is believed that photoresist masks are more susceptible to charging, so that using photoresist masks may increase ARDE. As feature sizes decrease, RIE-lag problems increase.

One way to reduce the ARDE is to increase ion energy by increasing the bias voltage. However, increasing the bias voltage increases faceting. It would be desirable to reduce or more preferably eliminate ARDE or RIE-lag and be able to tune a desired amount of faceting. Having some faceting may make the features easier to fill.

One unexpected result found by an embodiment of the invention is that the halogen to carbon ratio of the etch gas may be adjusted to adjust faceting without affecting RIE-lag or ARDE. Therefore, a bias voltage may be selected to reduce or preferably eliminate RIE-lag or ARDE and then a halogen to carbon ratio may be found to tune the faceting to a desired faceting. This property is shown through the following graphs.

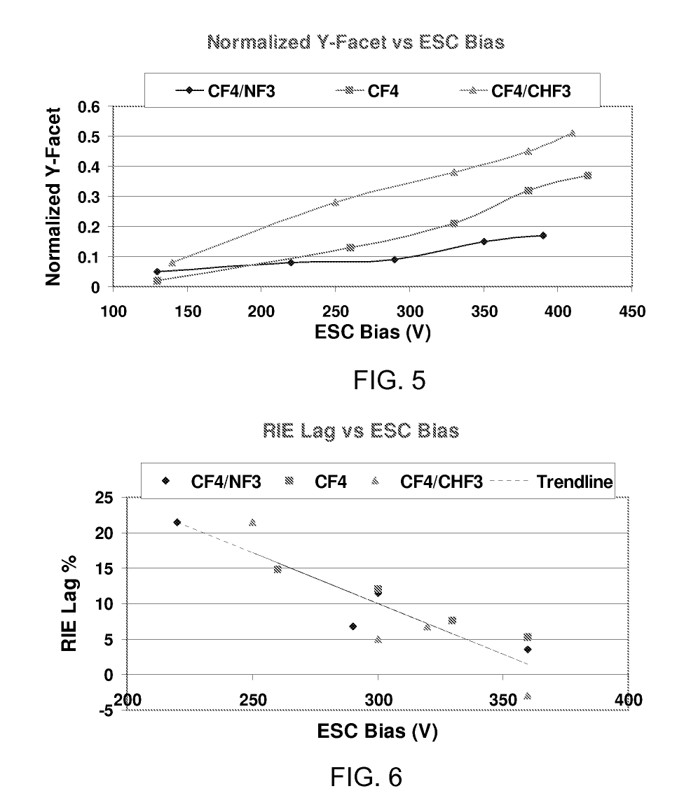

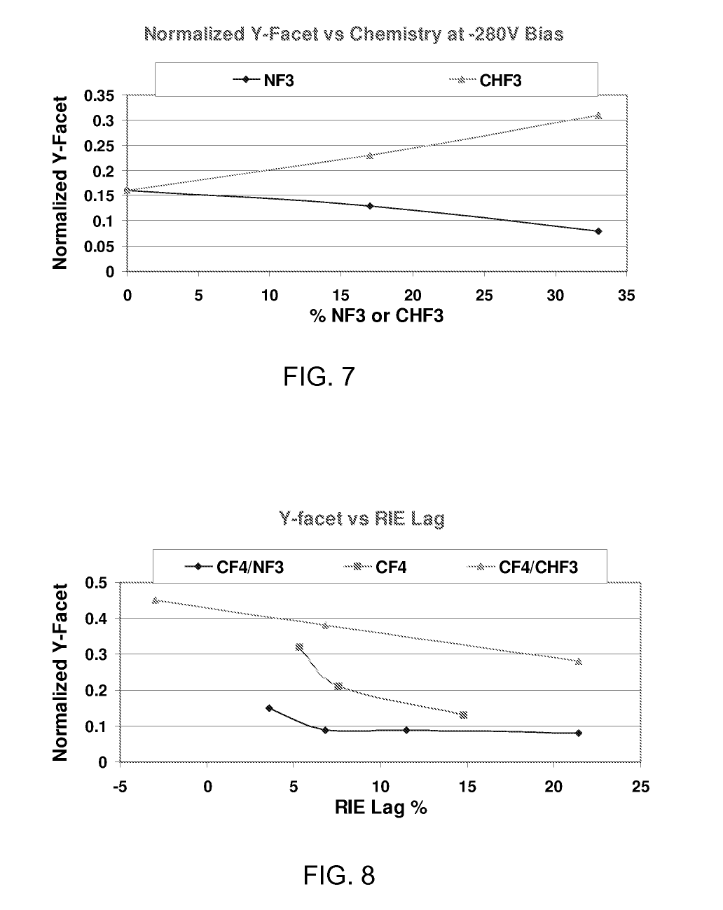

FIG. 5 is a graph of normalized Y-facet versus ESC bias for different etch chemistries of CF₄/NF₃, CF₄, and CF₄/CHF₃. Generally, as ESC bias increases faceting increases, although the different etch chemistries have different slopes. FIG. 6 is a graph of RIE lag (RIE lag=(Low aspect ratio trench depth−High aspect ratio trench depth)/Low aspect ratio trench depth) versus ESC bias for the different etch chemistries. Generally, as ESC bias increases RIE lag decreases for the different chemistries. FIG. 7 is a graph of normalized Y-facet versus chemistry at −280 volt bias for NF₃ and CHF₃. As the percentage of NF₃ increases, the Y-facet decreases. As the percentage, of CHF₃ increases the Y-facet increases. Therefore the ratio of NF₃ to CHF₃ in the etch gas may be used to tune faceting. FIG. 8 is a graph of normalized Y-facet versus RIE lag for CF₄, NF₃, and CHF₃. This graph shows that normalized y-facet can be tuned independently of RIE lag when the proper chemistry ratio is used. Otherwise, a tradeoff exists between faceting and RIE lag.

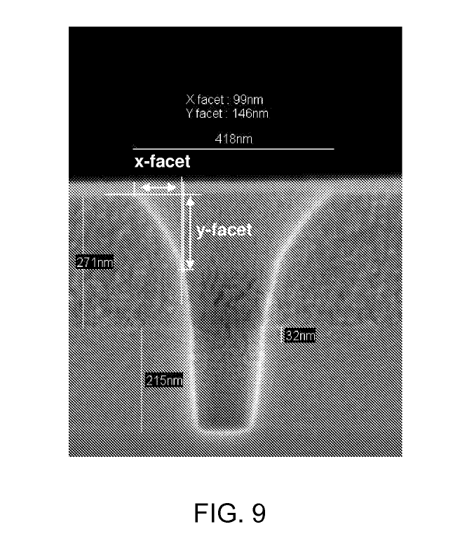

FIG. 9 illustrates how the x-facet and y-facet are measured. Normalized y-facet is set to equal (y-facet)/(trench depth).

Although different mask materials may be used as mask for the etching process, preferably, the mask is a photoresist mask. Although different materials may be etched by this process, preferably the layer that is etched is a dielectric layer. More preferably, the layer that is etched is a low-k dielectric layer, where k<3.0. More preferably, the low-k dielectric layer is porous. The reason that the mask is preferably a photoresist mask and the layer to be etched is a porous low-k dielectric layer is that with such a combination it is especially difficult to reduce or eliminate ARDE while tuning the faceting. The inventive method is able to solve such a problem with various materials and masks and in addition solve the special difficulty provided by the above specific combination. The features may be subsequently filled with a conductive material to form conductive contacts. The tuning of the facets allows for improved conductive contacts, by providing a faceting that provides optimum electrical contacts.

As aspect ratios increase, the ability to tune faceting increases in importance. The use of higher bias may be preferred for other reasons than reducing RIE-lag.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A method of designing an etch recipe, comprising:
a) performing an etch, comprising:
providing an etch gas with a set halogen to carbon ratio;
forming a plasma from the etch gas; and
etching trenches over vias;
b) measuring via faceting; and
c) resetting the halogen to carbon ratio according to the measured via faceting, where the halogen to carbon ratio is increased if too much faceting is measured and the halogen to carbon ratio is decreased if too little faceting is measured, and then repeating steps a to c, until a desired amount of faceting is obtained.

2. The method, as recited in claim 1, wherein the halogen is fluorine.

3. The method, as recited in claim 2, further comprising measuring aspect dependent ratio etching (ARDE), wherein the resetting the halogen to carbon ratio does not significantly impact ARDE.

4. The method, as recited in claim 3, wherein the performing the etch provides a bias sufficient to minimize aspect dependent ratio etching.

5. The method, as recited in claim 4, further comprising selecting a bias voltage, wherein the selected bias voltage eliminates ARDE.

6. The method, as recited in claim 4, wherein a photoresist mask is disposed over a layer that is etched.

7. The method, as recited in claim 6, wherein the layer that is etched is a dielectric layer.

8. The method, as recited in claim 7, wherein the dielectric layer is a low-k dielectric layer, wherein k<3.0.

9. The method, as recited in claim 8, wherein the low-k dielectric layer is porous.

10. The method, as recited in claim 9, further comprising etching a plurality of trenches over vias in a plurality of wafers using the halogen to carbon ratio used for obtaining the desired amount of faceting.

11. The method, as recited in claim 10, further comprising filling the plurality of trenches over vias with a conductive material.

12. The method, as recited in claim 1, further comprising etching a plurality of wafers using the halogen to carbon ratio used for obtaining the desired amount of faceting.

13. The method, as recited in claim 1, further comprising adjusting electrostatic chuck bias to minimize aspect dependent ratio etching.

14. A semiconductor device made by the method of claim 1.

15. A method of manufacturing semiconductor devices, comprising:
a) performing an etch, comprising:
providing an etch gas with a set halogen to carbon ratio;
forming a plasma from the etch gas; and
etching trenches over vias;
b) measuring via faceting;
c) resetting the halogen to carbon ratio according to the measured via faceting, where the halogen to carbon ratio is increased if too much faceting is measured and the halogen to carbon ratio is decreased if too little faceting is measured, and then repeating steps a to c, until a desired amount of faceting is obtained; and
d) etching a plurality a plurality of trenches over vias in a plurality of wafers using the halogen to carbon ratio used for obtaining the desired amount of faceting.

16. The method, as recited in claim 15, wherein the halogen is fluorine.

17. The method, as recited in claim 16, further comprising filling the plurality of trenches over vias with a conductive material.

18. The method, as recited in claim 19, further comprising measuring aspect dependent ratio etching (ARDE), wherein the resetting the halogen to carbon ratio does not significantly impact ARDE.

19. The method, as recited in claim 18, wherein the performing the etch provides a bias sufficient to minimize aspect dependent ratio etching.
